(19) United States
(12) Patent Application Publication
(10) Pub. No.: US 2026/0060016 A1
(43) Pub. Date: Feb. 26, 2026

(54) SUBSTRATE PROCESSING INCLUDING INITIAL ETCHING AND FAST ETCHING, AND RELATED METHODS, APPARATUS, SYSTEMS, AND CHAMBERS

(71) Applicant: Applied Materials, Inc., Santa Clara, CA (US)

(72) Inventors: Yi-Chiau HUANG, Fremont, CA (US); Saurabh CHOPRA, Santa Clara, CA (US); Jason JEWELL, Santa Clara, CA (US)

(21) Appl. No.: 18/814,133

(22) Filed: Aug. 23, 2024

(51) Int. Cl. H01L 21/3065; H01J 37/32; H01L 21/02

(52) U.S. Cl. CPC H01L 21/3065; H01J 37/32449; H01L 21/02532; H01J 2237/3341

(57) ABSTRACT

Embodiments described herein generally relate to semiconductor device fabrication, and more particularly, to systems and methods that include initial etching and fast etching. In one or more embodiments, a method of substrate processing includes etching a layer of a substrate using a first pressure and a first composition including hydrogen chloride. The etching includes flowing the first composition for a first time period and at a first flow rate. The method includes etching the layer using a second pressure and a second composition including chlorine (Cl2) gas, and the etching includes flowing the second composition for a second time period less than the first time period and at a second flow rate less than the first flow rate. The second time period is a time ratio of the first time period, and the time ratio is 1:15 or less.

### BACKGROUND

### Field

Embodiments described herein generally relate to semiconductor device fabrication, and more particularly, to systems and methods that include initial etching and fast etching.

### Description of the Related Art

Processing (such as for n-type metal-oxide semiconductor (MOS) devices) can be limited with respect to speed and selectivity. As an example, processing using relatively low temperatures can make etching slow, which can delay manufacturing and cause lower throughput. Moreover, limited selectivity can erode deposition and can hinder device performance. Cyclic processing can compound issues. For example, cyclic processing can cause processing times of 1 hour or higher.

Therefore, there is a need for methods and systems that can process semiconductor devices in a manner that is quick, efficient, and selective.

### SUMMARY

Embodiments described herein generally relate to semiconductor device fabrication, and more particularly, to systems and methods that include initial etching and fast etching.

In one or more embodiments, a method of substrate processing includes etching a layer of a substrate using a first pressure and a first composition including hydrogen chloride. The etching includes flowing the first composition for a first time period and at a first flow rate. The method includes etching the layer using a second pressure and a second composition including chlorine (Cl₂) gas, and the etching includes flowing the second composition for a second time period less than the first time period and at a second flow rate less than the first flow rate. The second time period is a time ratio of the first time period, and the time ratio is 1:15 or less.

In one or more embodiments, a method of substrate processing includes depositing a layer on a substrate using a first temperature and a first pressure, and etching the layer using a second pressure, a second temperature, and a first composition including hydrogen chloride. The etching includes flowing the first composition for a first time period and at a first flow rate. The method includes etching the layer using a third pressure, a third temperature, and a second composition including chlorine (Cl₂) gas, and the etching includes flowing the second composition for a second time period and at a second flow rate less than the first flow rate. The second time period is less than the first time period, and the third pressure is lower than the first pressure and the second pressure.

In one or more embodiments, a processing system includes a processing chamber that includes a chamber body at least partially defining a processing volume, a substrate support disposed in the processing volume, and one or more heat sources operable to heat the processing volume. The processing system includes a controller including instructions that when executed cause a plurality of operations to be conducted. The plurality of operations includes etching using a first pressure, a first temperature, and a first composition including hydrogen chloride. The etching includes flowing the first composition for a first time period and at a first flow rate. The plurality of operations include etching using a second pressure, a second temperature, and a second composition including chlorine (Cl₂) gas, and the etching includes flowing the second composition for a second time period and at a second flow rate less than the first flow rate. The second time period is less than the first time period, and the second pressure is lower than the first pressure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic top view of a multi-chamber processing system, according to one or more embodiments of the present disclosure.

FIG. 2 is a cross sectional view of a processing chamber, according to one or more embodiments.

FIG. 3 is a cross-sectional view of a film structure that includes doped semiconductor layers, according to one or more embodiments.

FIG. 4 depicts a flow diagram of a method 400 of substrate processing, according to one or more embodiments.

FIGS. 5A-5D are cross-sectional views of a portion of the film structure corresponding to various states of the method 400, according to one or more embodiments.

FIG. 6A is a schematic side cross-sectional view of a device, according to one or more embodiments.

FIG. 6B is a schematic side cross-sectional view of the device with source or drain structures formed on the semiconductor fins, according to one or more embodiments.

FIG. 7 is a schematic isometric view of the device, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to semiconductor device fabrication, and more particularly, to systems and methods that include initial etching and fast etching. The fast etching follows the initial etching. In one or more embodiments, the initial etching includes hydrogen chloride and the fast etching includes chlorine gas (Cl₂). The embodiments can form silicon layer(s) having dopants (such as phosporus). The doped semiconductor epitaxial layers can be use, for example, as source/drain structures in an n-type metal-oxide semiconductor (NMOS) device. The methods include cyclic deposition and etch operations, which facilitates fast and selective epitaxial growth of the doped semiconductor layers.

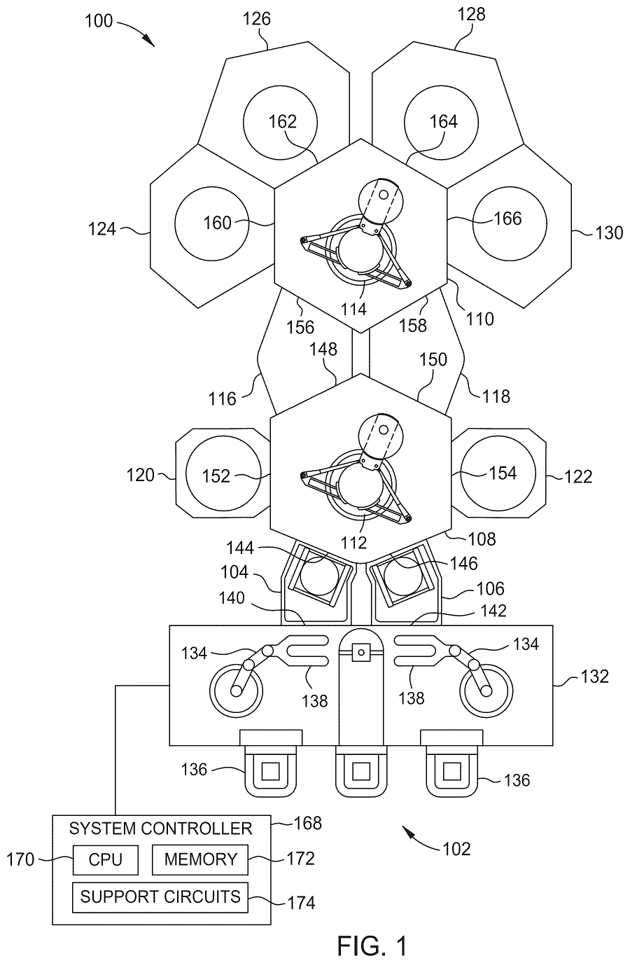

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port can be closed.

The load lock chambers 104, 106, transfer chambers 108, 110, holding chambers 116, 118, and processing chambers 120, 122, 124, 126, 128, 130 may be fluidly coupled to a gas and pressure control system. The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In one or more examples, the processing chamber 120 can be capable of performing an etch process, the processing chamber 122 can be capable of performing a cleaning process, the processing chamber 124 can be capable of performing a selective removal process, and the processing chambers 126, 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, 128, or 130 may be a Centura™ Epi chamber available from Applied Materials of Santa Clara, Calif. The present disclosure contemplates that the deposition operations and the etching operations described herein can be conducted in the same chamber (such as in the same deposition chamber) or can be conducted in multiple chambers.

A controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as read only memory (ROM) (e.g., electrically erasable programmable read-only memory (EEPROM)), flash memory (e.g., flash drive), floppy disk, hard disk, random access memory (RAM) (e.g., non-volatile random access memory (NVRAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), or any other form of digital storage, local or remote. The support circuits 174 are coupled to the CPU 170 and may comprise cache, clock circuits, input/output subsystems, power supplies, and the like. The various methods disclosed herein (such as the method 400) may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

The instructions stored in the memory 172 of the controller 168 can include one or more machine learning/artificial intelligence algorithms that can be executed in addition to the operations described herein. As an example, a machine learning/artificial intelligence algorithm executed by the controller 168 can generate, prioritize, accept, and/or reject signal profiles and/or data (such as metrology data and/or substrate map data) used in relation to the method 400. The machine learning/artificial intelligence algorithm can account for previous operational runs to monitor and update the signal profiles and/or data. The machine learning/artificial intelligence algorithm can optimize process parameter(s) of process recipes. The one or more machine learning/artificial intelligence algorithms can use, for example, a regression model (such as a linear regression model) or a clustering technique to estimate optimized parameters and/or optimized values for signal profiles and/or data. The algorithm(s) can be unsupervised or supervised. In one or more embodiments, the controller 168 automatically conducts the operations described herein without the use of one or more machine learning/artificial intelligence algorithms. In one or more embodiments, the controller 168 compares measurements to data in a look-up table and/or a library to optimize process parameters. The controller 168 can store measurements as data in the look-up table and/or the library.

Other processing systems can be in other configurations. For example, more or fewer processing chambers may be coupled to a transfer apparatus. In the illustrated example, the transfer apparatus includes the transfer chambers 108, 110 and the holding chambers 116, 118. In one or more examples, more or fewer transfer chambers (e.g., one transfer chamber) and/or more or fewer holding chambers (e.g., no holding chambers) may be implemented as a transfer apparatus in a processing system.

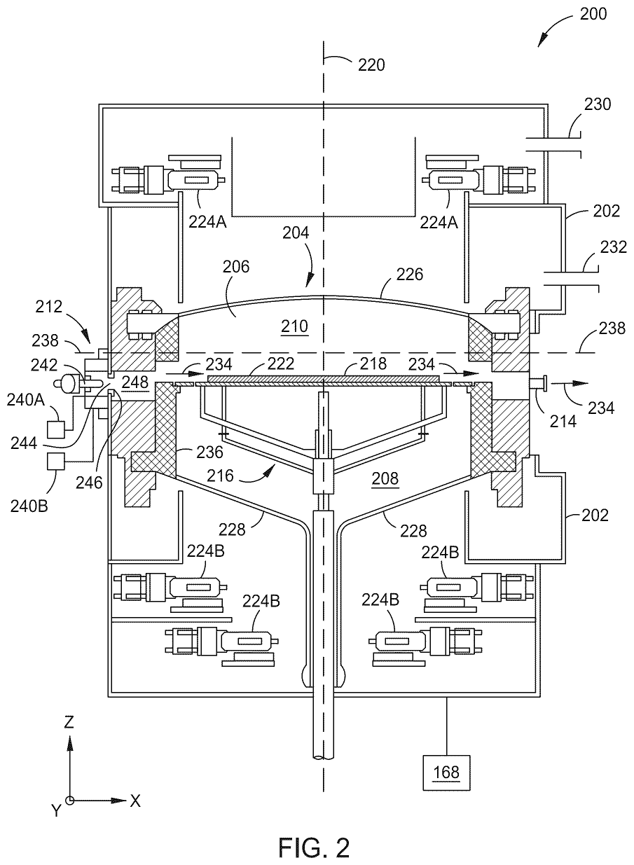

FIG. 2 is a cross sectional view of a processing chamber 200, according to one or more embodiments. In one or more embodiments, the processing chamber 200 is configured to conduct an epitaxial (Epi) deposition process as detailed below. The processing chamber 200 may be the processing chamber 126, 128, or 130 shown in FIG. 1.

The processing chamber 200 includes a housing structure 202 made of a process resistant material, such as aluminum or stainless steel, for example 216L stainless steel. The housing structure 202 encloses various functioning elements of the processing chamber 200, such as a chamber 204, which includes an upper chamber 206, and a lower chamber 208, in which a processing volume 210 is contained. The chamber 204 can be, for example, a quartz chamber. Reactive species are provided to the chamber 204 by a gas distribution assembly 212, and processing byproducts are removed from the processing volume 210 by an outlet port 214, which is typically in communication with a vacuum source (not shown).

A substrate support 216 is adapted to receive a substrate 218 that is transferred to the processing volume 210. The substrate support 216 is disposed along a longitudinal axis 220 of the processing chamber 200. The substrate support 216 may be made of a ceramic material or a graphite material coated with a silicon material, such as silicon carbide, or other process resistant material. Reactive species from precursor reactant materials are applied to a surface 222 of the substrate 218, and byproducts may be subsequently removed from the surface 222 of the substrate 218. Heating of the substrate 218 in the processing volume 210 may be provided by radiation sources, such as upper heat sources 224A (e.g., lamps) and lower heat sources 224B (e.g., lamps). The present disclosure contemplates that other heat sources may be used (in addition to or in place of the lamps) for the various heat sources described herein. For example, resistive heaters, light emitting diodes (LEDs), and/or lasers may be used for the various heat sources described herein.

In one or more embodiments, the upper heat sources 224A and the lower heat sources 224B are infrared (IR) lamps. Non-thermal energy or radiation from the heat sources 224A and 224B travels through an upper transparent plate 226 (such as an upper quartz window) of the upper chamber 206, and through a lower transparent plate 228 (such as a lower quartz window) of the lower chamber 208. Cooling gases for the upper chamber 206, if needed, enter through an inlet 230 and exit through an outlet 232. Precursor reactant materials, as well as diluent, purge and vent gases for the processing chamber 200, enter through the gas distribution assembly 212 and exit through the outlet port 214. While the upper transparent plate 226 is shown as being curved or convex, the upper transparent plate 226 may be planar or concave as the pressure on both sides of the upper transparent plate 226 is substantially the same (e.g., at atmospheric pressure).

The low wavelength radiation in the processing volume 210, which is used to energize reactive species and assist in adsorption of reactants and desorption of process byproducts from the surface 222 of the substrate 218, typically ranges from about 0.8 μm to about 1.2 μm, for example, between about 0.95 μm to about 1.05 μm, with combinations of various wavelengths being provided, depending, for example, on the composition of the film which is being epitaxially grown.

The component gases enter the processing volume 210 via the gas distribution assembly 212. Gas flows from the gas distribution assembly 212 and exits through the outlet port 214 as shown generally by a flow path 234. Combinations of component gases, which are used to clean/passivate a substrate surface, or to form the silicon and/or germanium-containing film that is being epitaxially grown, are typically mixed prior to entry into the processing volume 210. The overall pressure in the processing volume 210 may be adjusted by a valve (not shown) on the outlet port 214. At least a portion of the interior surface of the processing volume 210 is covered by a liner 236. In one or more embodiments, the liner 236 comprises a quartz material that is opaque. In this manner, the chamber wall is insulated from the heat in the processing volume 210.

The temperature of surfaces in the processing volume 210 may be controlled within a temperature range of about 200° C. to about 600° C., or greater, by the flow of a cooling gas, which enters through the inlet 230 and exits through the outlet 232, in combination with radiation from the upper heat sources 224A positioned above the upper transparent plate 226. The temperature in the lower chamber 208 may be controlled within a temperature range of about 200° C. to about 600° C. or greater, by adjusting the speed of a blower unit which is not shown, and by radiation from the lower heat sources 224B disposed below the lower chamber 208. The pressure in the processing volume 210 may be between about 0.1 Torr to about 600 Torr, such as between about 5 Torr to about 30 Torr.

The temperature on the surface 222 of the substrate 218 may be controlled by power adjustment to the lower heat sources 224B in the lower chamber 208, or by power adjustment to both the upper heat sources 224A overlying the upper transparent plate 226, and the lower heat sources 224B in the lower chamber 208. The power density in the processing volume 210 may be between about 40 W/cm² to about 400 W/cm², such as about 80 W/cm² to about 120 W/cm². Other power densities are contemplated.

In one or more embodiments, the gas distribution assembly 212 is disposed normal to, or in a radial direction 238 relative to, the longitudinal axis 220 of the processing chamber 200 or the substrate 218. In this orientation, the gas distribution assembly 212 is adapted to flow process gases in the radial direction 238 across, or parallel to, the surface 222 of the substrate 218. In one processing application, the process gases are preheated at the point of introduction to the processing chamber 200 to initiate preheating of the gases prior to introduction to the processing volume 210, and/or to break specific bonds in the gases. In this manner, surface reaction kinetics may be modified independently from the thermal temperature of the substrate 218.

In operation, precursors used to form silicon (Si) and silicon germanium (SiGe) blanket or selective epitaxial films are provided to the gas distribution assembly 212 from one or more gas sources 240A and 240B. IR lamps 242 (one is shown in FIG. 2) may be utilized to heat the precursors within the gas distribution assembly 212 as well as along the flow path 234. The gas sources 240A, 240B may be coupled the gas distribution assembly 212 in a manner adapted to facilitate introduction zones within the gas distribution assembly 212, such as a radial outer zone and a radial inner zone between the outer zones when viewed in from a top plan view. The gas sources 240A, 240B may include valves to control the rate of introduction into the zones.

The gas sources 240A, 240B may include silicon precursors such as silanes, including silane (SiH₄), disilane (Si₂H₆), dichlorosilane (SiH₂Cl₂), trichlorosilane, hexachlorodisilane (Si₂Cl₆), dibromosilane (SiH₂Br₂), higher order silanes, derivatives thereof, and combinations thereof. The gas sources 240A, 240B may also include germanium containing precursors, such as germane (GeH₄), digermane (Ge₂H₆), germanium tetrachloride (GeCl₄), dichlorogermane (GeH₂Cl₂), derivatives thereof, and combinations thereof. The silicon and/or germanium containing precursors may be used in combination with hydrogen chloride (HCl), chlorine gas (Cl₂), hydrogen bromide (HBr), and combinations thereof. The gas sources 240A, 240B may include one or more of the silicon and germanium containing precursors in one or both of the gas sources 340A, 340B.

The precursor materials enter the processing volume 210 through openings or holes 244 (one is shown in FIG. 2) in the perforated plate 246 in this excited state, which in one embodiment is a quartz material, having the holes 244 formed therethrough. The perforated plate 246 is transparent to IR energy, and may be made of a clear quartz material. In one or more embodiments, the perforated plate 246 may be any material that is transparent to IR energy and is resistant to process chemistry and other processing chemistries. The energized precursor materials flow toward the processing volume 210 through the holes 244 in the perforated plate 246, and through channels 248 (one is shown in FIG. 2). A portion of the photons and non-thermal energy from the IR lamps 242 also passes through the holes 244, the perforated plate 246, and channels 248 facilitated by a reflective material and/or surface disposed on the interior surfaces of the gas distribution assembly 212, thereby illuminating the flow path 234 of the precursor materials. In this manner, the vibrational energy of the precursor materials may be maintained from the point of introduction to the processing volume 210 along the flow path.

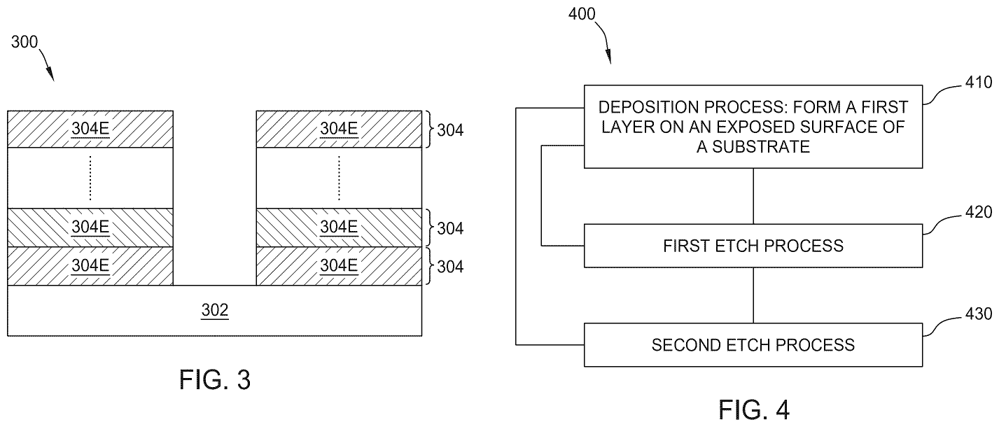

FIG. 3 is a cross-sectional view of a film structure 300 that includes doped semiconductor layers 304, according to one or more embodiments. In one or more embodiments, the film structure 300 is a semiconductor structure. Doped semiconductor layers 304, such as doped with n-type carrier dopants, such as phosphorous, may be used as a source/drain in n-channel metal-oxide semiconductor (NMOS) devices.

The film structure 300 includes a substrate 302, and a stack of doped semiconductor epitaxial layers 304 formed on the substrate 302. The substrate 302 can include a layer of material that serves as a basis for subsequent processing operations and includes a surface to be cleaned. The substrate 302 may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

The doped semiconductor epitaxial layers 304 are formed of silicon (Si) or silicon germanium (SiGe) with a ratio of germanium (Ge) ranging between 20% and 100%. The doped semiconductor epitaxial layers 304 may be doped with n-type carrier dopants such as phosphorus (P) or antimony (Sb). The concentration can be between about 10¹⁹ cm⁻³ and 5·×10²¹ cm⁻³, depending upon the desired conductive characteristic of the film structure 300. The doped semiconductor epitaxial layers 304 may be doped with p-type carrier dopants such as boron (B), gallium (Ga), aluminum (Al), or indium (In). The concentration can be between about 10²⁰ cm⁻³ and 5×·10²¹ cm⁻³, depending upon the desired conductive characteristic of the film structure 300.

The doped semiconductor epitaxial layers 304 may respectively have a thickness of between about 15 Å and about 20 Å. The film structure 300 may have about 30 doped semiconductor epitaxial layers 304, and can have a total thickness of between about 500 Å and about 700 Å, for example, about 600 Å.

As described below, the doped semiconductor epitaxial layers 304 are cyclically formed by depositing a doped silicon layer and etching the doped silicon layer.

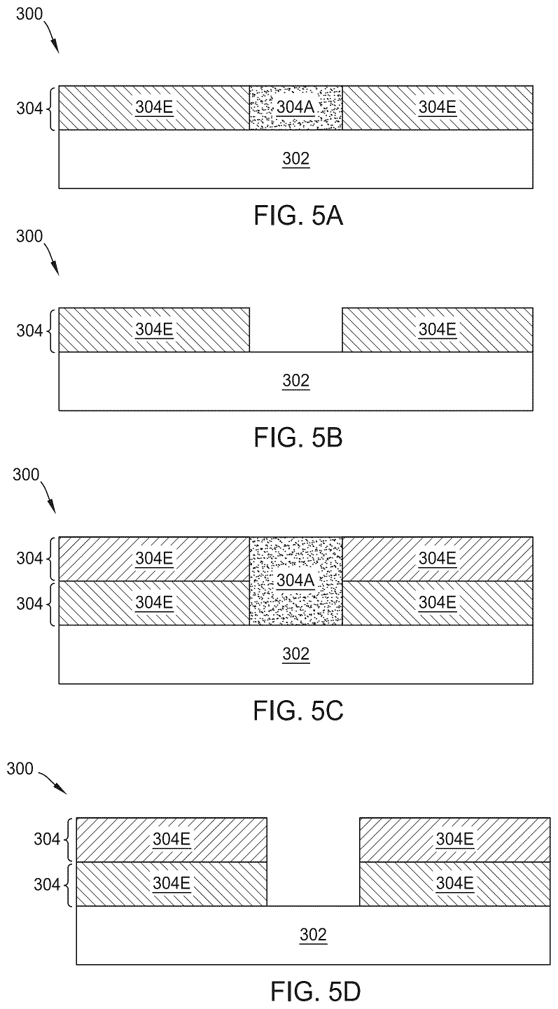

FIG. 4 depicts a flow diagram of a method 400 of substrate processing, according to one or more embodiments. FIGS. 5A-5D are cross-sectional views of a portion of the film structure 300 corresponding to various states of the method 400, according to one or more embodiments. It should be understood that FIGS. 5A-5D illustrate only partial schematic views of the film structure 300, and the film structure 300 may contain any number of transistor sections, dielectric layers, and additional materials that are omitted from FIGS. 3 and 5A-5D. It should also be noted that although the method illustrated in FIG. 4 is described sequentially, other process sequences that include one or more operations that have been omitted and/or added, and/or has been rearranged in another order, fall within the scope of the present disclosure.

The method 400 begins with operation 410, in which a deposition process is performed to deposit a first layer (e.g., a doped semiconductor layer 304) on an exposed surface of the substrate 302, as shown in FIG. 5A. The deposition uses a first temperature and a first pressure. The deposition process may include any suitable deposition technique, such as epitaxial (Epi) deposition, chemical vapor deposition (CVD), atomic layer deposition (ALD), or physical vapor deposition (PVD), by flowing a deposition gas in a processing chamber, such as the processing chamber 126, 128, or 130 shown in FIG. 1, or the processing chamber 200 shown in FIG. 2.

In one or more embodiments, the first layer is formed of silicon (Si) or silicon germanium (SiGe) with a ratio of germanium (Ge) ranging between 20% and 100%. The first layer may be doped with n-type carrier dopants such as phosphorus (P) or antimony (Sb) with the concentration between about 10¹⁹ cm⁻³ and 5·×10²¹ cm⁻³, depending upon the desired conductive characteristic of the film structure 300. The first layer may be doped with p-type carrier dopants such as boron (B), gallium (Ga), aluminum (Al), or indium (In) with the concentration of between about 10²⁰ cm⁻³ and 5×·10²¹ cm⁻³, depending upon the desired conductive characteristic of the film structure 300.

In one or more embodiments, the deposition gas used in the deposition process includes a silicon-containing precursor, a germanium containing precursor, and/or a dopant source. The precursor gas(es) and/or the dopant(s) can be carried in a carrier gas (such as hydrogen gas and/or nitrogen gas). The silicon-containing precursor may include silane (SiH₄), disilane (Si₂H₆), trisilane, tetrasilane (Si₄H₁₀), or a combination thereof. The germanium-containing precursor may include germane (GeH₄), germanium tetrachloride (GeCl₄), and digermane (Ge₂H₆). An n-type dopant source may include phosphine (PH₃), phosphorus trichloride (PCl₃), triisobutylphosphine ([(CH₃)₃C]₃P), antimony trichloride (SbCl₃), Sb(C₂H₅)₅, arsine (AsH₃), arsenic trichloride (AsCl₃), or tertiarybutylarsine (AsC₄H₁₁). A p-type dopant source may include diborane (B₂H₆), or boron trichloride (BCl₃).

In the deposition process at operation 410, the first layer (e.g., the doped semiconductor layer 304), as deposited, may include an epitaxial portion 304E and an amorphous portion 304A, due to, for example, different nucleation rates of the doped semiconductor layer 304 on a surface of a semiconductor region (e.g., silicon (Si) or silicon germanium (SiGe)) of the substrate 302 and on a surface of a dielectric region (e.g., silicon dioxide (SiO₂) or silicon nitride (Si₃N₄)) of the substrate 302. The nucleation may occur at a faster rate on the surface of the semiconductor region than on the surface of the dielectric region, and thus an epitaxial portion 304E of the doped semiconductor layer 304 may be formed selectively on the surface of the semiconductor region while an amorphous portion 304A of the doped semiconductor layer 304 may be formed on the surface of the dielectric region. The amorphous portion 304A of the doped semiconductor layer 304 may be removed in the subsequent etch process in operation 430. In one or more embodiments, the deposition process includes flowing deposition gas for a time period that is 100 seconds or higher, such as 110 seconds to 130 seconds, for example 120 seconds.

The first temperature of the deposition is less than 550 degrees Celsius, such as less than 450 degrees Celsius. The first pressure is within a range of 5 Torr to 600 Torr. In one or more embodiments the first pressure is within a range of 100 Torr to 500 Torr, such as 100 Torr to 450 Torr. In one or more embodiments, the first temperature is 450 degrees Celsius or less, such as 400 degrees Celsius or less. In one or more embodiments, the first temperature is within a range of 400 degrees Celsius to 450 degrees Celsius.

At operation 420, a first etch process is conducted. The first etch process includes etching the first layer using a second pressure, a second temperature, and a first composition including hydrogen chloride. In one or more embodiments, the first composition includes hydrogen chloride (HCl) gas carried in a carrier gas (such as nitrogen gas and/or hydrogen gas). The etching of the first etch process includes flowing the first composition for a first time period and at a first flow rate. The first time period can be equal to or greater than the time period of the deposition. The second pressure is within a range of 100 Torr to 600 Torr. In one or more embodiments, the second pressure is within a range of 550 Torr to 600 Torr, such as 595 Torr to 600 Torr. In one or more embodiments, the second pressure is greater than the first pressure. In one or more embodiments, the second temperature is less than 550 degrees Celsius. In one or more embodiments, the second temperature is 450 degrees Celsius or less, such as 400 degrees Celsius or less. In one or more embodiments, the second temperature is within a range of 400 degrees Celsius to 450 degrees Celsius.

At operation 430, a second etch process is conducted. The second etch process includes etching the first layer using a third pressure, a third temperature, and a second composition including chlorine (Cl₂) gas. In one or more embodiments, the second composition includes chlorine gas carrier in a carrier gas (such as nitrogen gas). The chlorine gas of the second etch process is a flow ratio relative to the hydrogen chloride of the first etch process. In one or more embodiments, the flow ratio is at least 1,000:1. In one or more embodiments, the second composition flows after the flow of the first composition ends. In one or more embodiments, the second composition flows simultaneously with (e.g., co-flows with) the flow of the first composition. The present disclosure contemplates that the second composition can flow during at least part of the flow first composition, and after the flow of the first composition ends.

The first composition has a first flow ratio of HCl:carrier gas, and the second composition has a second flow ratio of Cl₂:carrier gas. The first flow ratio is greater than the second flow ratio by a factor of at least ten.

The etching of the second etch process includes flowing the second composition at a second flow rate less than the first flow rate. In one or more embodiments, the second time period is less than the first time period, the third pressure is lower than the first pressure and the second pressure, and the third temperature is less than or equal to the first temperature and the second temperature. In one or more embodiments, the third temperature is 250 degrees or higher, such as within a range of 250 degrees Celsius to 550 degrees Celsius. In one or more embodiments, the third temperature is within a range of 250 degrees Celsius to 450 degrees Celsius, for example 250 degrees Celsius to 400 degrees Celsius. The third pressure is within a range of 5 Torr to 80 Torr, such as 15 Torr to 50 Torr. In one or more embodiments, the third pressure is within a range of 15 Torr to 25 Torr (such as 20 Torr), or 35 Torr to 45 Torr (such as 40 Torr). The second temperature can be equal to the first temperature.

The second time period of the second etch process is a time ratio of the first time period of the first etch process, and the time ratio is 1:15 or less, such as 1:20 or less. In one or more embodiments, the time ratio is 1:40 or less. In one or more embodiments, the time ratio is 1:60 or less. The second time period is 20.0 seconds or less. In one or more embodiments the second time period is less than 10.0 seconds, such as less than 5.0 seconds. In one or more embodiments, the second time period is greater than 5.0 seconds and less than 10.0 seconds. Other values are contemplated for the second time period. The first time period is 120 seconds or higher, such as within a range of 170 seconds to 190 seconds, for example 180 seconds. In one or more embodiments, the second time period is within a range of 1.0 second to 3.5 seconds. In one or more embodiments, the first time period is within a range of 1.0 second to 3.0 seconds.

In one or more embodiments, the first etch process uses a relatively high pressure and a relatively high flow rate, and the second etch process uses a relatively low pressure and a relatively low flow rate.

The present disclosure contemplates other values for the temperatures, the pressures, and the time periods described herein. For example, higher temperatures are contemplates for the first temperature and the second temperature. The present disclosure contemplates that the deposition of operation 410 and the first etch process of operation 420 can use the same pressure, the same temperature, and the same flow rate. The present disclosure contemplates that the second etch process of operation 430 can use a lower pressure, a lower temperature, and a lower flow rate than the deposition and the first etch process.

The first composition of the first etch process etches one or more sections of the first layer, and the second composition of the second etch process etches the one or more sections at a faster rate than the first composition. In one or more embodiments, the one or more sections are amorphous, such as an amorphous portion 304A of the doped semiconductor layer 304, as shown in FIG. 5B. The one or more sections (e.g., the amorphous portion 304A) are selectively etched relative to one or more other sections (e.g., epitaxial portions 304E).

A cycle of the deposition process in operation 410, the first etch process in operation 420, and the second etch process in operation 430 may be repeated, as shown in FIGS. 5C and 5D, as needed to obtain an overall thickness of the doped semiconductor epitaxial layers 304. The overall thickness can be, for example, within a range of 500 Å to 700 Å, for example, 600 Å. The cycle (including sequentially operations 410, 420, and 430) may be repeated one or more additional times for a plurality of cycles. In one or more embodiments, first composition of operation 420 begins to flow after the flowing of the deposition gas of operation 410 ends, and the second composition of operation 430 begins to flow after the flowing of the first composition of operation 420 ends.

In one or more embodiments, the second etch process of operation 430 is conducted for each cycle of a plurality of cycles. In one or more embodiments, the second etch process of operation 430 is conducted after the plurality of cycles are completed, which can decrease gas consumption, increase throughput, and decrease processing delays. For example, a plurality of cycles can be conducted that alternate operation 410 and operation 420, and operation 430 is conducted a single time after the final cycle of operation 410 then operation 420. In such an example, the method 400 can be repeated for a plurality of method cycles such that for each method cycle: the method 400 is conducted such that the plurality of cycles are conducted for operations 410, 420 (e.g., operations 410, 420 are alternately repeated) and then a final etch of operation 430 is conducted.

In one or more embodiments, the second etch process of operation 430 is conducted at cycle intervals of the plurality of cycles. For example, the second etch process can be conducted every three cycles. That is, two cycles can include operations 410, 420 and then a third cycle can include all of operations 410, 420, 430. The present disclosure contemplates that during operation 420 and prior to operation 430, the second composition including the chlorine gas can co-flow with the first composition including hydrogen chloride. The co-flow in operation 420 can be conducted for each cycle of the plurality of cycles.

In such an embodiment involving the co-flow, a small fraction of Cl₂ is flowed in operation 420 such that the method 400 can be expressed in the following first exemplary formula: {[(SiP deposition)+ ((HCl+Cl₂) etch))}×(n cycles)]+ (Cl₂ etch), where n is a positive integer. In the first exemplary formula, a process starts with operation 410 and then operation 420 alternately conducted for “n” number of cycles, and at the end of the “n” number of cycles operation 430 is conducted. In such an embodiment involving both the co-flow and the method cycles described above, the method 400 can be expressed in the following second exemplary formula: < {[(SiP deposition)+ ((HCl+Cl₂) etch))]×(n cycles)}+ (Cl₂ etch)>×(m cycles), where n and m are both positive integers. In the second exemplary formula, a process starts with operation 410 and then operation 420 alternately conducted for “n” number of cycles, and at the end of the “n” number of cycles operation 430 is conducted, and the process is repeated for ‘m” number of cycles. In one or more embodiments, the second time period of operation 420 is greater than the time period of operation 410, and the third time period of operation 430 is less than the time period of operation 410 such that the time periods can be expressed as: (HCl etch)> (SiP deposition)> (Cl₂ final etch). In the exemplary formulas referred to herein, “(SiP deposition)” represents the deposition conducted in operation 410, “(HCl”) represents the first etch process in operation 420, “(HCl+Cl₂) etch)” represents the first etch process in operation 420 in which the hydrogen chloride and chlorine gas are co-flowed into the processing chamber, and “(Cl₂ final etch)” represents the second etch process in operation 430. In the exemplary formulas referred to herein, “m cycles” represents the number of method cycles for which all the operations 410, 420, and 430 are conducted in the overall method 400. In the exemplary formulas referred to herein, “n cycles” represents the number of cycles for which operation 410 and operation 420 are alternately conducted within the method 400 for each m cycle. In the exemplary formulas referred to herein, “x” represents multiplication and “+” represents addition.

The embodiments described herein can provide methods and system for forming a contact epitaxial layer within a trench on a selected portion of a transistor structure. The layers formed may be n-type MOS (e.g., silicon) layers formed on an n-type MOS device. The doped silicon layers can be used as source/drain in a NMOS device.

The present disclosure contemplates that the operations and methods described herein may use plasma. For example, the deposition of operation 410, the etching of operation 420, and/or the etching of operation 430 may use plasma to facilitate the activation of gases to assist in deposition and/or etching. As an example, nitrogen gas and/or hydrogen gas may be used to ignite the plasma. Other plasma compositions are contemplated. The plasma may be generated using a variety of apparatus. For example, the plasma can be generated in the processing volume 210 in a capacitive-coupled (CCP) manner or an inductive-coupled (ICP) manner. As another example, the plasma can be generated in a remote plasma source and can be supplied into the processing 210 from a side of the processing chamber 200 or a top of the processing chamber 200. For example, the plasma can be supplied from the side of the processing chamber 200 through the same gas flow path as the process deposition gases (e.g., through the same gas distribution assembly 212).

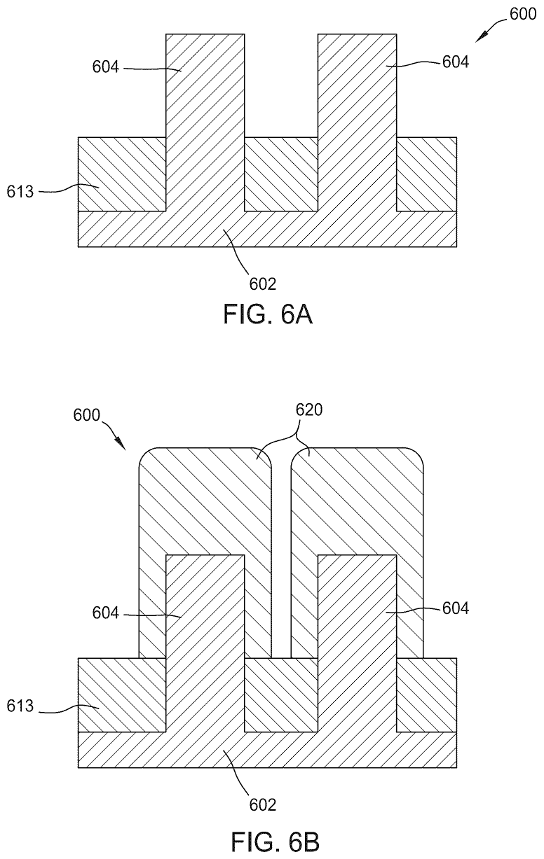

FIG. 6A is a schematic side cross-sectional view of a device 600, according to one or more embodiments. The device 600 includes a substrate 602, semiconductor fins 604 formed on the substrate 602, and dielectric material 613 between the semiconductor fins 604. In one or more embodiments, the fins 604 include one or more of silicon, silicon germanium, or germanium.

FIG. 6B is a schematic side cross-sectional view of the device 600 with source or drain structures 620 formed on the semiconductor fins 604, according to one or more embodiments. The source or drain structures 620 include the epitaxial layers 304 formed using the method 400.

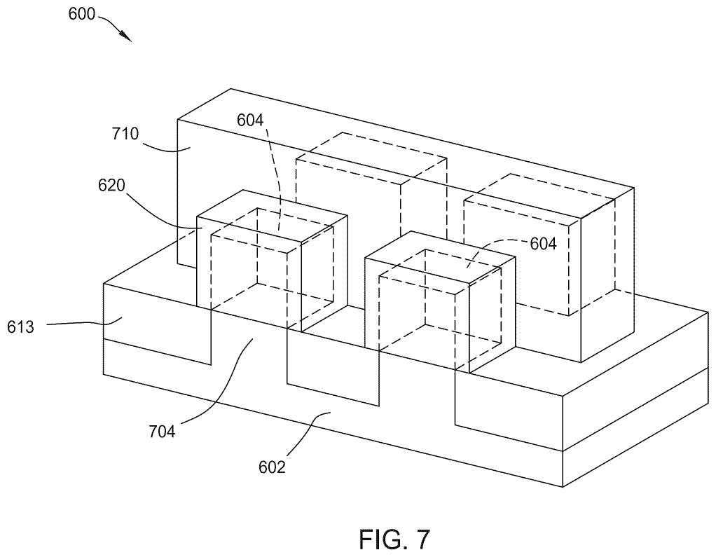

FIG. 7 is a schematic isometric view of the device 600, according to one or more embodiments. FIG. 7 further includes a gate electrode 710 between the fins 604 and on the dielectric material 613. The present disclosure contemplates that sections 704 of the fins 604 can extend upwardly past an upper surface of the dielectric material 613 and into the source or drain structures 620. In one or more embodiments, a material is disposed between the source or drain structures 620 and the gate electrode 710. In one or more embodiments, the material is a gate dielectric. In one or more embodiments, the material includes one or more of silicon dioxide, silicon nitride, silicon carbonitride, or silicon oxycarbonitride. In one or more embodiments, the plurality of source or drain structures 620 include a plurality of source structures 620 on one side of the gate electrode 710 and a plurality of drain structures 620 on another side of the gate electrode 710.

Benefits of the present disclosure include low temperature (e.g., 450 degrees Celsius or lower) processing, fast processing, and selective processing. As an example, the present disclosure facilitates low temperature etching that is fast and is selective. The subject matter can form phosphorus doped silicon layers having a high phosphorus dopant concentration. The dopant concentration facilitates selectively growing silicon layers on silicon window(s) of the substrate relative to dielectric portions of the substrate. For example, the first etch process facilitates selectively etching amorphous portions of doped silicon layers relative to portions of the doped silicon layers on the silicon window(s), and the second etch process facilitates fast etching at low temperatures. Benefits also include reduced dopant diffusion, increased throughput, and enhanced device performance (such as high conductivity).

It is contemplated that one or more aspects disclosed herein may be combined. As an example, one or more aspects, features, components, operations, and/or properties of the processing system 100, the processing chamber 200, the film structure 300, the method 400, the process flow and/or structures shown in FIGS. 5A-5D, and/or the device 600 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

1. A method of substrate processing, comprising:
etching a layer of a substrate using a first pressure and a first composition including hydrogen chloride, the etching comprising flowing the first composition for a first time period and at a first flow rate; and
etching the layer using a second pressure and a second composition including chlorine (Cl₂) gas, the etching comprising flowing the second composition for a second time period less than the first time period and at a second flow rate less than the first flow rate, the second time period is a time ratio of the first time period, and the time ratio is 1:15 or less.

2. The method of claim 1, wherein the first pressure is within a range of 100 Torr to 600 Torr, and the second pressure is within a range of 5 Torr to 80 Torr.

3. The method of claim 1, wherein the second time period is 20.0 seconds or less, and the first time period is 120 seconds or higher.

4. The method of claim 1, wherein the etching using the first composition includes a first temperature, and the etching using the second composition includes a second temperature that is less than the first temperature.

5. The method of claim 4, wherein the first temperature is less than 550 degrees Celsius, and the second temperature is 250 degrees Celsius or higher.

6. The method of claim 1, wherein the flowing of the second composition begins after the flowing of the first composition ends.

7. The method of claim 1, wherein the second composition flows simultaneously with the first composition, and a flow ratio of the hydrogen chloride relative to the chlorine (Cl₂) gas is at least 1,000:1.

8. The method of claim 1, wherein the first composition has a first flow ratio of HCl:carrier gas, the second composition has a second flow ratio of Cl₂:carrier gas, and the first flow ratio is greater than the second flow ratio by a factor of at least ten.

9. A method of substrate processing, comprising:
depositing a layer on a substrate using a first temperature and a first pressure;
etching the layer using a second pressure, a second temperature, and a first composition including hydrogen chloride, the etching comprising flowing the first composition for a first time period and at a first flow rate; and
etching the layer using a third pressure, a third temperature, and a second composition including chlorine (Cl₂) gas, the etching comprising flowing the second composition for a second time period and at a second flow rate less than the first flow rate, the second time period is less than the first time period, and the third pressure is lower than the first pressure and the second pressure.

10. The method of claim 9, wherein the first pressure within a range of 100 Torr to 500 Torr, the second pressure is within a range of 100 Torr to 600 Torr, and the third pressure is within a range of 5 Torr to 80 Torr.

11. The method of claim 9, wherein the depositing and the etching using the first composition are conducted sequentially and are repeated for a plurality of cycles that alternates the depositing and the etching.

12. The method of claim 11, wherein the etching using the second composition is conducted after the plurality of cycles are completed.

13. The method of claim 11, wherein the etching using the second composition is conducted at cycle intervals of the plurality of cycles.

14. The method of claim 11, wherein the depositing forms a silicon layer having a dopant, the first composition etches one or more sections of the silicon layer, and the second composition etches the one or more sections at a faster rate than the first composition.

15. The method of claim 9, wherein the third temperature is less than the first temperature and the second temperature the first time period is 120 seconds or higher, and the second time period is 20.0 seconds or less.

16. A processing system, comprising:
a processing chamber comprising:
a chamber body at least partially defining a processing volume,
a substrate support disposed in the processing volume, and
one or more heat sources operable to heat the processing volume; and
a controller comprising instructions that when executed cause a plurality of operations to be conducted, the plurality of operations comprising:
etching using a first pressure, a first temperature, and a first composition including hydrogen chloride, the etching comprising flowing the first composition for a first time period and at a first flow rate, and
etching using a second pressure, a second temperature, and a second composition including chlorine (Cl₂) gas, the etching comprising flowing the second composition for a second time period and at a second flow rate less than the first flow rate, the second time period is less than the first time period, and the second pressure is lower than the first pressure.

17. The processing system of claim 16, wherein the second time period is a time ratio of the first time period, and the time ratio is 1:15 or less.

18. The processing system of claim 16, wherein the first pressure is within a range of 100 Torr to 600 Torr, and the second pressure is within a range of 5 Torr to 80 Torr.

19. The processing system of claim 16, wherein the second time period is 20.0 seconds or less, and the first time period is 120 seconds or higher.

20. The processing system of claim 16, wherein the first temperature is less than 550 degrees Celsius, and the second temperature is 250 degrees Celsius or higher.
